(19) United States
(12) Patent Application Publication
(10) Pub. No.: US 2018/0217459 A1
(43) Pub. Date: Aug. 2, 2018

(54) ARRAY SUBSTRATE, LIQUID CRYSTAL DISPLAY PANEL AND DISPLAY DEVICE

(71) Applicant: Shenzhen China Star Optoelectronics Technology Co. Ltd., Shenzhen, Guangdong (CN)

(72) Inventors: Yue WU, Shenzhen, Guangdong (CN); Weina YONG, Shenzhen, Guangdong (CN); Bangyin PENG, Shenzhen, Guangdong (CN)

(73) Assignee: Shenzhen China Star Optoelectronics Technology Co., Ltd., Shenzhen, Guangdong (CN)

(21) Appl. No.: 15/125,194

(22) PCT Filed: Jul. 29, 2016
(86) PCT No.: PCT/CN2016/092323

§ 371 Date: Sep. 12, 2016

(30) Foreign Application Priority Data
Jun. 24, 2016 (CN) 201610466448.1

(51) Int. Cl. G02F 1/1362; G02F 1/1368; H01L 27/12

(52) U.S. Cl. CPC G02F 1/136227; H01L 27/124; G02F 1/136286; G02F 1/1368

(57) ABSTRACT

The present disclosure provides an array substrate and a liquid crystal display panel, the array substrate includes a plurality of gate lines spaced in parallel and a plurality of data lines spaced in parallel, a plurality of pixel areas are orthogonally disposed the plurality of gate lines and the plurality of data lines; the plurality of gate lines and the plurality of data line are insulated orthogonal, the each pixel area includes a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode.

### CROSS REFERENCE

The present disclosure claims the priority of No. 201610466448.1, entitled “array substrate, liquid crystal display panel and display device”, filed on Jun. 24, 2016, the disclosure of which is incorporated herein by reference in its entirety.

### FIELD OF THE DISCLOSURE

The present disclosure relates to a liquid crystal display panel technology field, and more particularly to an array substrate and a liquid crystal display panel.

### BACKGROUND OF THE DISCLOSURE

With the continuous development of the electronic technology, the liquid crystal display device is widely used in each display field, the thin film transistor (TFT) array substrate is an important part of the liquid crystal display device, it can achieve the display effect of high speed, high brightness and high contrast, it has become the mainstream of many flat panel display technology. Wherein, the array substrate includes a gate line, a data line, a pixel electrode, a TFT, etc. with the improvement of the display performance requirements, the increasingly high demand for the pixel, the pixel units on the unit area of the display device are more and more, the each pixel unit will become smaller and smaller. Since the via hole connected with the pixel electrode is located outside of the pixel electrode and in the pixel area, need to take up some area of the pixel area, reducing the transparent area in the pixel area, these essential components will reduce the aperture ratio of each pixel unit, and with the pixel higher, the influence of the aperture ratio of the pixel is greater.

### SUMMARY OF THE DISCLOSURE

The object of the present disclosure is providing an array substrate and a liquid crystal display panel increasing the aperture ratio.

The present disclosure provides an array substrate, the array substrate includes a plurality of gate lines spaced in parallel and a plurality of data lines spaced in parallel, a plurality of pixel areas are orthogonally disposed the plurality of gate lines and the plurality of data lines; the plurality of gate lines and the plurality of data lines are insulated orthogonal,

the each pixel area includes a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode.

Wherein, the pixel electrode is provided with an extension area, the TFT switch is at the one side of the extension area, the via hole is opened in the extension area and through the layer where the data line of the array substrate is located.

Wherein, the TFT switch includes a source electrode and a drain electrode, the via hole connects the drain electrode, the source electrode connects the data line.

Wherein, the plurality of gate lines are arranged spaced along the first direction and are extended along the second direction; the plurality of data lines are arranged spaced along the second direction and are extended along the first direction; each two data lines and gate lines are cross surrounded the sub-pixel area.

Wherein, the TFT switch includes a gate electrode, the gate is electrically connected the gate line.

The liquid crystal display panel of the present disclosure includes an array substrate, a liquid crystal layer and a color film substrate, wherein, the array substrate includes a plurality of gate lines spaced in parallel and a plurality of data lines spaced in parallel, a plurality of pixel areas are orthogonally disposed the plurality of gate lines and the plurality of data lines; the plurality of gate lines and the plurality of data lines are insulated orthogonal, the each pixel area includes a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode, the liquid crystal layer is between the array substrate and the color film substrate.

Wherein, the pixel electrode is provided with an extension area, the TFT switch is at the one side of the extension area, the via hole is opened in the extension area.

Wherein, the TFT switch includes a gate electrode, a source electrode and a drain electrode, the via hole is electrically connected with the source electrode, the gate electrode is electrically connected with the gate line.

Wherein, the plurality of gate lines are arranged spaced along the first direction and are extended along the second direction; the plurality of data lines are arranged spaced along the second direction and are extended along the first direction; each two data lines and gate lines are cross surrounded the sub-pixel area.

The present disclosure provides a display device, the display device includes a liquid crystal display panel and a backlight module, the liquid crystal display panel is arranged on the backlight module to provide the light source through the backlight module.

The array substrate of the present disclosure is arranged the via hole connected with the TFT switch and the pixel electrode in the pixel electrode area, avoid taking up the area of the other parts of the pixel area and increasing the shading area, to avoid reducing the aperture ratio of the pixel area and increasing the transmittance of the pixel area.

### BRIEF DESCRIPTION OF THE DRAWINGS

In order to more clearly illustrate the embodiments or the prior art technical solutions embodiment of the present disclosure, it will implement the following figures for the cases described in the prior art or the need to use a simple introduction. Apparently, the following description the drawings are only some embodiments of the present disclosure, those of ordinary skill in speaking, without creative efforts of the premise, but also can derive other drawings from these drawings.

FIG. 1 is a perspective plan diagram of the portion area of the array substrate of the present disclosure provided.

### DETAILED DESCRIPTION OF PREFERRED EMBODIMENTS

The following with the present disclosure that reference implementation, carried a clear example of the technical solutions of the present disclosure, a complete description, it is clear that the described embodiments are merely part of the embodiments of the present disclosure, but not all embodiments example. Based on the embodiments of the present disclosure, those of ordinary skill in not making all other embodiments without creative efforts obtained, are within the scope of the present disclosure is protected.

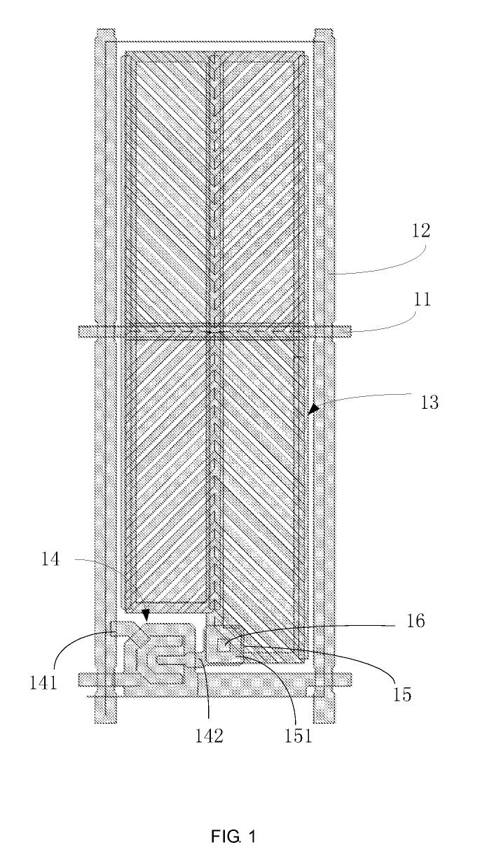

Please refer to FIG. 1, the preferred embodiment of the present disclosure is provides an array substrate and a liquid crystal display panel, the liquid crystal display panel includes an array substrate 11, a color film substrate and a liquid crystal layer between the array substrate 11 and the color film substrate. The array substrate 10 includes a plurality of gate lines 11 spaced in parallel and a plurality of data lines 12 spaced in parallel, a plurality of pixel areas 13 are orthogonally disposed the plurality of gate lines 11 and the plurality of data lines 12; the plurality of gate lines 11 and the plurality of data lines 12 are insulated orthogonal. The plurality of pixel area 13 are arranged in a matrix.

The each pixel area 13 includes a TFT switch 14, a pixel electrode 15. The TFT switch 14 connects the gate line 11 and data line 12 of the pixel area 13 where the TFT switch 14 is located. A via hole 16 is arranged in the pixel electrode 15. The via hole 16 is arranged adjacent to the TFT switch 14, the pixel electrode 15 is electrically connected through the via hole 16 and the TFT switch 14 arranged in the pixel electrode 15.

In the present embodiment, the plurality of gate lines 11 are arranged spaced along the first direction and are extended along the second direction; the first direction is longitudinal, the second direction is transverse. The plurality of data lines are arranged spaced along the second direction and are extended along the first direction; each two data lines 12 and gate lines 11 are cross surrounded the sub-pixel area 13. The first direction is perpendicular to the horizontal direction.

In the present embodiment, the pixel electrode 15 is provided with an extension area 151, the TFT switch 14 is at the one side of the extension area 151, the via hole 16 is opened in the extension area 151. Specifically, a vacancy area is formed between the extension area 151 and the data line, the TFT is arranged in the vacancy area, the via hole 16 is opened in the extension area 151 through the insulating layer, for connecting the pixel electrode 15 and the source and drain.

Further, the TFT switch 14 includes the source electrode 14 and the drain electrode 142, the via hole 16 is connected with the drain electrode 142, the source electrode 141 connects the data line 12.

Further, the TFT switch 14 includes a gate electrode (not shown), the gate electrode is electrically connected the gate line 11.

In the array substrate of the present disclosure, the via hole 16 connected with the TFT switch 14 and the pixel electrode 15 in the pixel electrode 15 area, avoid taking up the area of the other parts of the pixel area 13 and increasing the shading area, avoid the influence of the aperture ratio of the pixel area and increasing the transmittance of the pixel area.

The present disclosure provides a display device, the display device includes the liquid crystal display panel and the backlight module, the liquid crystal display panel is arranged on the backlight module, and the light source is provided through the backlight module.

Disclosed above is only a preferred embodiment of the present disclosure only, of course, not in order to define the scope of the claimed disclosure, those of ordinary skill in achieving the above embodiments can be understood that all or part of the process, and by It made claims of the disclosure identical change, which is still covered by the scope of the disclosure.

What is claimed is:

1. An array substrate, wherein, the array substrate comprises a plurality of gate lines spaced in parallel and a plurality of data lines spaced in parallel, a plurality of pixel areas are orthogonally disposed the plurality of gate lines and the plurality of data lines; the plurality of gate lines and the plurality of data lines are insulated orthogonal,
the each pixel area comprises a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode.

2. The array substrate according to claim 1, wherein, the pixel electrode is provided with an extension area, the TFT switch is at the one side of the extension area, the via hole is opened in the extension area and through the layer where the data line of the array substrate is located.

3. The array substrate according to claim 1, wherein, the TFT switch comprises a source electrode and a drain electrode, the via hole connects the drain electrode, the source electrode connects the data line.

4. The array substrate according to claim 1, wherein, the plurality of gate lines are arranged spaced along the first direction and are extended along the second direction; the plurality of data lines are arranged spaced along the second direction and are extended along the first direction; each two data lines and gate lines are cross surrounded the sub-pixel area.

5. The array substrate according to claim 1, wherein, the TFT switch comprises a gate electrode, the gate is electrically connected the gate line.

6. A liquid crystal display panel comprises an array substrate, a liquid crystal layer and a color film substrate, wherein, the array substrate comprises a plurality of gate lines spaced in parallel and a plurality of data lines spaced in parallel, a plurality of pixel areas are orthogonally disposed the plurality of gate lines and the plurality of data lines; the plurality of gate lines and the plurality of data lines are insulated orthogonal, the each pixel area comprises a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode, the liquid crystal layer is between the array substrate and the color film substrate.

7. The liquid crystal display panel according to claim 6, wherein, the pixel electrode is provided with an extension area, the TFT switch is at the one side of the extension area, the via hole is opened in the extension area.

8. The liquid crystal display panel according to claim 6, wherein, the TFT switch comprises a gate electrode, a source electrode and a drain electrode, the via hole is electrically connected with the source electrode, the gate electrode is electrically connected with the gate line.

9. The liquid crystal display panel according to claim 6, wherein, the plurality of gate lines are arranged spaced along the first direction and are extended along the second direction; the plurality of data lines are arranged spaced along the second direction and are extended along the first direction; each two data lines and gate lines are cross surrounded the sub-pixel area.

10. A display device, wherein, the display device comprises a liquid crystal display panel and a backlight module, the liquid crystal display panel is arranged on the backlight module to provide the light source through the backlight module, wherein the liquid crystal display panel comprises an array substrate, a liquid crystal layer and a color film substrate, the array substrate comprises a plurality of gate lines spaced in parallel and a plurality of data lines spaced in parallel, a plurality of pixel areas are orthogonally disposed the plurality of gate lines and the plurality of data lines; the plurality of gate lines and the plurality of data lines are insulated orthogonal, the each pixel area comprises a TFT switch, a pixel electrode, the TFT switch connects the gate line and data line of the pixel area where the TFT switch is located, a via hole is arranged in the pixel electrode, the via hole is arranged adjacent to the TFT switch, the pixel electrode is electrically connected through the via hole and the TFT switch arranged in the pixel electrode, the liquid crystal layer is between the array substrate and the color film substrate.

11. The display device according to claim 10, wherein, the pixel electrode is provided with an extension area, the TFT switch is at the one side of the extension area, the via hole is opened in the extension area.

12. The display device according to claim 10, wherein, the TFT switch comprises a gate electrode, a source electrode and a drain electrode, the via hole is electrically connected with the source electrode, the gate electrode is electrically connected with the gate line.

13. The display device according to claim 10, wherein, the plurality of gate lines are arranged spaced along the first direction and are extended along the second direction; the plurality of data lines are arranged spaced along the second direction and are extended along the first direction; each two data lines and gate lines are cross surrounded the sub-pixel area.
